(19) United States
(12) Patent Application Publication
(10) Pub. No.: US 2016/0098339 A1
(43) Pub. Date: Apr. 7, 2016

(54) SMART POWER SCHEDULING FOR USER-DIRECTED BATTERY DURATION

(71) Applicant: QUALCOMM Incorporated, San Diego, CA (US)

(72) Inventors: Sathish Kumar Masilamani, Bangalore (IN); Vinay Reddy Venumuddala, Bangalore (IN); Dhruv Arya, Bangalore (IN)

(21) Appl. No.: 14/507,708

(22) Filed: Oct. 6, 2014

(51) Int. Cl. G06F 11/34; G01R 21/00; G06F 1/26; G06F 11/30

(52) U.S. Cl. CPC G06F 11/3442; G06F 11/3433; G06F 11/3024; G01R 21/00; G06F 1/26

(57) ABSTRACT

The systems and method described herein provide smart power scheduling for an electronic device. A user can specify a desired battery duration for the electronic device. Smart power scheduling can modify operation of the electronic device, when appropriate, so that the desired battery duration is met. The user may, for example, know that she will be unable to charge her smartphone for 10 hours and specify a desired battery duration of 10 hours. If during the 10 hours, the user plays a game on the smartphone that drains the battery too fast to meet the 10-hour desired battery duration, the smartphone can modify its operations, for example, by lowering the graphics resolution, to achieve the user-specified desired battery duration. When smart power scheduling modifies operations, it may limit the impact on the user experience, for example, background tasks may be modified before foreground tasks are modified.

### FIELD

The present invention relates to electronic devices and, more particularly, to systems and methods for power scheduling to provide a user-directed battery duration.

### BACKGROUND

An electronic device powered by a battery has a limited operating time due to discharge of the battery. The operating time (battery duration) will vary with battery charge. The battery duration will also vary with how the electronic device is used. In a complex electronic device, such as a smartphone, the variation in battery duration with how the electronic device is used can be very large. For example, battery duration when the smartphone is used for streaming video may be one-tenth of the battery duration when the smartphone is used for voice calls which may be one-tenth of the battery duration when the smartphone is idle.

The variation in battery duration makes it difficult for a phone's user to know how long the phone will operate. For example, if the user is on an airplane flight and wishes to make a phone call upon landing, the user does not know much (and for what tasks) she can use the phone during the flight.

An electronic device that can operate for a user-defined battery duration would provide convenience and an improved experience for the user. Effective and efficient power scheduling to provide user-defined battery duration is difficult to achieve with a user-level application since the user-level application may not be able to switch quickly between power states and may lack detailed information about current consumption.

### SUMMARY

In one aspect, method is provided for power scheduling in an electronic device including a plurality of cores operable in a plurality of power states. The method includes: receiving a user-defined battery duration; receiving activity information from the plurality of cores; determining, based on the activity information, whether the user-defined battery duration is supported; and in the case that the user-defined battery duration is not supported, determining a new power state for at least one of the plurality of cores.

In one aspect, an electronic device is provided that includes: a plurality of cores configured to provide functions of the electronic device and operable in a plurality of power states; a power manager module; and a smart power scheduler module configured to receive a user-defined battery duration, receive activity information from the plurality of cores, determine, based on the activity information, whether a user-defined battery duration is supported, in the case that the user-defined battery duration is not supported, determine a new power state for at least one of the plurality of cores, and signal the new power state to the power manager module, wherein the power manager module is configured to control the power states of the plurality of cores based at least in part on the new power state signaled by the smart power scheduler module.

In one aspect, an apparatus is provided that includes: a plurality of cores configured to provide functions of the apparatus and operable in a plurality of power states; and a means for controlling the power states of the plurality of cores configured to receive a defined battery duration from a user, receive activity information from the plurality of cores, determine, based on the activity information, whether a user-defined battery duration is supported, and in the case that the user-defined battery duration is not supported, determine a new power state for at least one of the plurality of cores.

Other features and advantages of the present invention should be apparent from the following description which illustrates, by way of example, aspects of the invention.

### BRIEF DESCRIPTION OF THE DRAWINGS

The details of the present invention, both as to its structure and operation, may be gleaned in part by study of the accompanying drawings, in which like reference numerals refer to like parts, and in which:

FIG. 1 is a functional block diagram of an electronic device with smart power scheduling according to a presently disclosed embodiment;

FIG. 2 is a flowchart of a process for smart power scheduling according to a presently disclosed embodiment; and

FIG. 3 is a graph that illustrates an example of smart power scheduling.

### DETAILED DESCRIPTION

The detailed description set forth below, in connection with the accompanying drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in simplified form in order to avoid obscuring such concepts.

Systems and methods for smart power scheduling are disclosed. These systems and methods allow a user to specify a desired battery duration for an electronic device. The desired battery duration indicates a minimum amount time that the user wants the electronic device to be able to operate. Smart power scheduling can modify operation of the electronic device, when appropriate, so that the desired battery duration is met. The user may, for example, know that she will be unable to charge her smartphone for 10 hours and specify a desired battery duration of 10 hours. If during the 10 hours, the user plays a game on the smartphone that drains the battery too fast to meet the 10-hour desired battery duration, the smartphone can modify its operations, for example, by lowering the graphics resolution, to achieve the user-specified desired battery duration. When smart power scheduling modifies operations, it may limit the impact on the user experience, for example, background tasks may be modified before foreground tasks are modified. Although smart power scheduling systems and methods for devices powered by batteries are described herein, smart power scheduling may be used with other energy sources, for example, ultracapacitors or fuel cells.

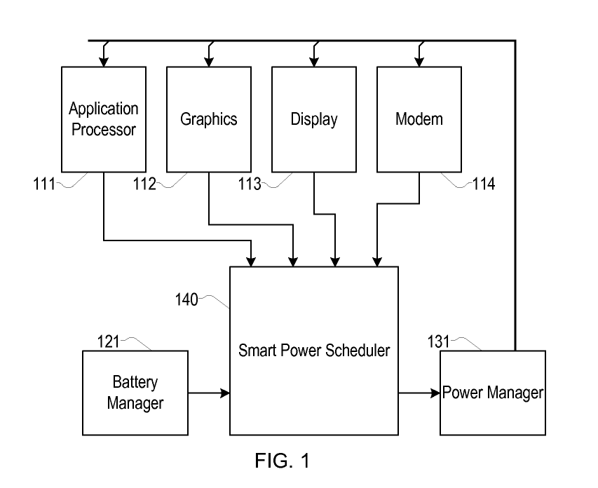

FIG. 1 is a functional block diagram of an electronic device with smart power scheduling according to a presently disclosed embodiment. The electronic device may be, for example, a smartphone or tablet computer. The electronic device is powered by a battery (or other limited energy source). The electronic device may be implemented using a system-on-a-chip (SoC) integrated circuit (IC). The electronic device includes a smart power scheduler module 140 that operates in conjunction with a power manager module 131 to control operating power levels of the electronic device.

The electronic device includes various cores that provide functions of the electronic device. Each core can consume energy from the battery. Many of the cores are circuits implemented in an SoC. In the embodiment of FIG. 1, the cores include an application processor module 111, a graphics module 112, a display module 113, and a modem module 114. The application processor module 111 executes application software for the electronic device. The graphics module 112 performs graphics processing for the electronic device. The display module 113 provides a display, for example, a touch screen, for the user of the electronic device. The modem module 114 provides communications, for example, LTE, Bluetooth, and Wi-Fi communications, for the electronic device. In other implementations, the electronic device may include additional cores, for example, an audio module, a video module, and a camera module.

The cores may operate in various power states. The power states are generally distinguished by requiring different levels of power to operate with the higher power states providing improved performance or greater functionality to the user. The power states of SoC-based cores may operate the associated circuitry at different frequencies, different voltages, or different frequencies and voltages. The application processor module 111, for example, may operate at higher frequencies and voltages in higher power states to provide faster or more concurrent functions for the user. The graphics module 112 may, for example, provide higher resolution images or higher frame rate video in higher power states. The display module 113 may, for example, provide a brighter display in higher power states. The modem module 114 may, for example, provide higher communication speeds in higher power states.

The power manager module 131 controls the operating power states of the cores. For example, the power manager module 131 may change the power state of the application processor module 111 by signaling a phase-locked loop to change the frequency of a clock signal supplied to the application processor module 111 and signaling a power management IC to change the voltage level of a power supply to the application processor module 111. The power manager module 131 may control the power states based in part on the operating state of the electronic device. For example, if the electronic device is idle, the cores can be put in their lowest power states. For many cores, the lowest power state is an off (or standby) state where no functions are provided to the electronic device. Other cores may not have an off power state. For example, the lowest power state of the modem module 114 may include sufficient functionality to enable the electronic device to receive calls. Some modules, such as the power manager module 131, may have only one power state. The power manager module 131 may control power states of the cores by selecting one of several device-level power states that specify combinations of power states of the individual cores.

The power manager module 131 can also control the power states of the cores based on signaling from the smart power scheduler module 140. The smart power scheduler module 140 can, for example, signal the power manager module 131 to switch the cores to particular power states in order to achieve a user-defined battery duration. The smart power scheduler module 140 may also signal the power manager module 131 that the smart power scheduler module 140 has no constraints for the power manager module 131. Since moving to new power states to achieve the user-defined battery duration may have a lower priority than task execution, in some cases, the power manager module 131 may not be able to switch to the power states signaled by the smart power scheduler module 140 while still allowing the electronic device to perform the functions requested by the user. The electronic device may then warn the user of a problem in achieving the user-defined battery duration.

The smart power scheduler module 140 receives a desired battery duration from the user of the electronic device. The user may, for example, enter the desired battery duration using the display module 113. The user may specify the desired battery duration in various forms, for example, as a duration (e.g., 16 hours) or a time point (e.g., 11:00 pm). The smart power scheduler module 140 also receives activity information from the cores. The activity information is indicative of power consumption. The activity information may, for example, indicate the amount of switching in CMOS circuits. The smart power scheduler module 140 converts the activity information into workload levels that indicate current consumptions of the cores. The smart power scheduler module 140 also receives information about the battery from a battery manager module 121. The battery information indicates, directly or indirectly, the charge level of the battery.

The smart power scheduler module 140 processes the workload levels and battery information to determine whether the electronic device expects to achieve the user-defined battery duration. The smart power scheduler module 140 can then signal the power manager module 131 to switch the cores to particular power states accordingly.

The smart power scheduler module 140 may be implemented, for example, using hardware or a combination of hardware and software. The smart power scheduler module 140 may be part of a system power and diagnostic monitor. Additionally, the smart power scheduler module 140 and the power manager module 131 may share common circuitry.

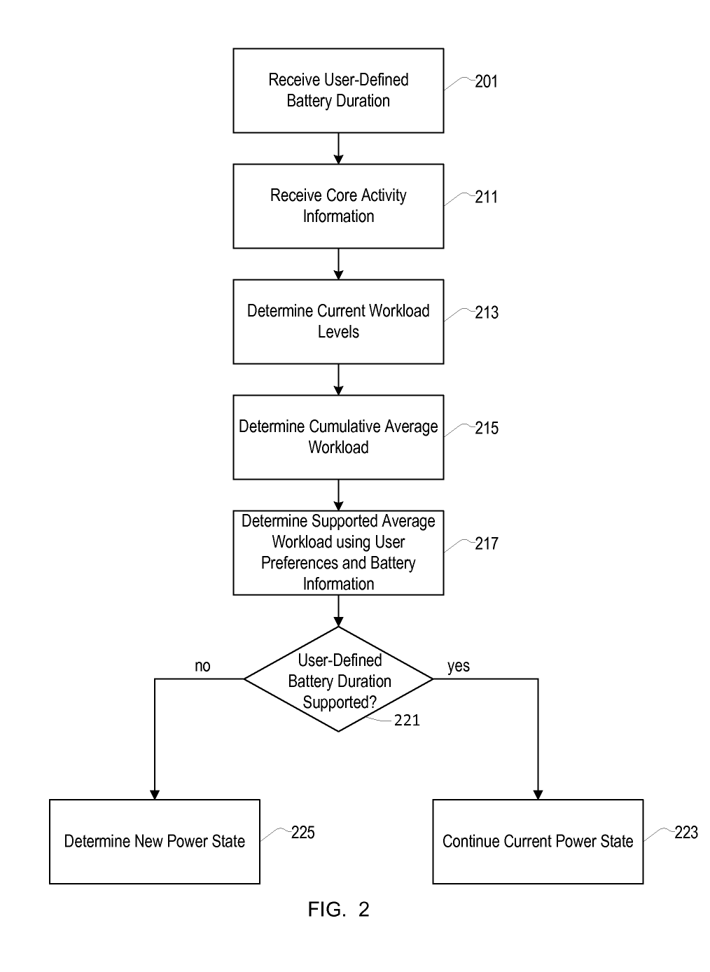

FIG. 2 is a flowchart of a process for smart power scheduling according to a presently disclosed embodiment. The process will be described with reference to the electronic device of FIG. 1; however, various embodiments of the process may be applied to any suitable apparatus.

In block 201, the electronic device receives a user-defined battery duration indicating a desired battery duration.

In block 211, the smart power scheduler module 140 receives activity information from the cores (111-114). The activity information may, for example, indicate an amount or rate of switching in the core.

In block 213, the smart power scheduler module 140 determines current workload levels based on the activity information received in block 211. The workload levels indicate current consumption (e.g., in milliamps) of the cores. Other measures of workload levels may also be used. The smart power scheduler module 140 may determine the current workload levels by combining the activity information from the cores with additional information such as voltage levels and clock frequencies of the associated cores. The smart power scheduler module 140 may also use per-core scaling factors in mapping the activity information to the current workload levels. Mapping from activity information to workload levels may use characterization data (e.g., one a per-model basis) obtained by running the electronic device in different use cases while measuring battery consumption.

In block 215, the smart power scheduler module 140 determines a cumulative average workload. The cumulative average workload indicates the average current consumption of the electronic device since a starting point. The starting point may be, for example, when the electronic device was turned on, when the user-specified the desired operating time, or when the electronic device began operating on battery power. The smart power scheduler module 140 may determine the cumulative average workload by computing a running average of the sum of the workload levels determined in block 213. Additional calculations may be used to determine the cumulative average workload, for example, a constant may be added to adjust for current draws from the battery that are not included in the activity information from the cores received in block 211.

In block 217, the smart power scheduler module 140 determines a current supported average workload. The supported average workload level is a workload level that, based on the state of the battery, the electronic device could sustain for the user-specified battery duration. For example, a battery with a battery charge level of 2200 mA-hr may have a supported average workload of 220 mA when 10 hours are remaining in the user-specified battery duration. The smart power scheduler module 140 may calculate the supported average workload, SAW as

$$SAW = \frac{Q}{{T}_{remaining}} - γ$$

where Q is the current battery change, T_{remaining} is the time remaining in the user-defined battery duration, and γ is factor to adjust for battery non-linearities. γ can be used to adjust, for example, for a non-linear relationship between battery charge and battery discharge rate. The smart power scheduler module 140 can use other relationships (e.g., a non-linear relationship) between battery charge and discharge rate to determine the supported average workload.

The battery charge may be based on battery measurements, for example, from the battery manager module 121. Alternatively or additionally, the smart power manager module may calculate the battery charge at the current analysis time by subtracting the current workload multiplied by the duration of the analysis time interval from the previous battery charge. The smart power manager module can analyze the measured battery charges and calculated battery charges to refine the information it uses to map activity levels to workloads in block 213.

In block 221, the smart power scheduler module 140 determines whether the user-defined battery duration is supported or changes to the power states are needed for the electronic device to achieve the user-defined battery duration. The smart power scheduler module 140 may, for example, compare the cumulative average workload from block 215 to the supported average workload from block 217. When the supported average workload is less than the cumulative average workload, the process determines that the user-defined battery duration is not supported. If the user-defined battery duration is not supported, the process continues to block 225; otherwise, the process continues to block 225. Whether the user-defined battery duration is supported may also be viewed as whether the current cumulative average workload is supported.

Block 223 is reached when the smart power scheduler module 140 has determined that changes are not currently needed for the electronic device to achieve the user-defined battery duration. The smart power scheduler module 140 may actively signal this information to the power manager module 131 or may convey this information implicitly by not signaling the power manager module 131 of a desired change in power states. In some cases, for example, when the cumulative average workload is much less than the supported average workload, the smart power scheduler module 140 may signal the power manager module 131 that it can increase power states.

In block 225, the smart power scheduler module 140 determines new power states for the cores. The smart power scheduler module 140 signals the new power states to the smart power scheduler module 140.

The smart power scheduler module 140 can use configuration information about the cores in determining new power states. The configuration information can include the number of power states available and expected workload levels associated with the power states. The smart power scheduler module 140 can also use learned information about the power states. For example, the smart power scheduler module 140 can use information about workload levels that occurred when the various power states were previously used.

The smart power scheduler module 140 can include user preferences in determining new power states. For example, the user may specify that audio quality is preferred over video quality or that Internet browsing speed is preferred over display quality.

The smart power scheduler module 140 can also include the current use case (e.g., telephone call, streaming video, using camera, or game playing) in determining new power states. The smart power scheduler module 140 may infer the use case from the core activity information, for example, high activity in the application processor module 111 and the graphics module 112 and low activity in the modem module 114 can indicate game playing.

The process may be performed at periodic time intervals, for example, every 0.2 hours. Other time intervals could also be used. Additionally, the time intervals may be dynamic, for example, with longer time intervals used when the electronic device is idle. Further, some blocks of the process may be performed at different time intervals, for example, blocks 211-215 may be performed more frequently than the remaining blocks. The duration of the time intervals may be selected to be short enough to provide accurate analysis and timely changes in power states. Additionally, the duration of the time intervals may be selected to be long enough to allow brief activities to proceed without intervention and to avoid frequent switches in power states, which could lower quality of user experience.

The process for smart power scheduling may be modified, for example, by adding, omitting, reordering, or altering steps. Additionally, steps may be performed concurrently.

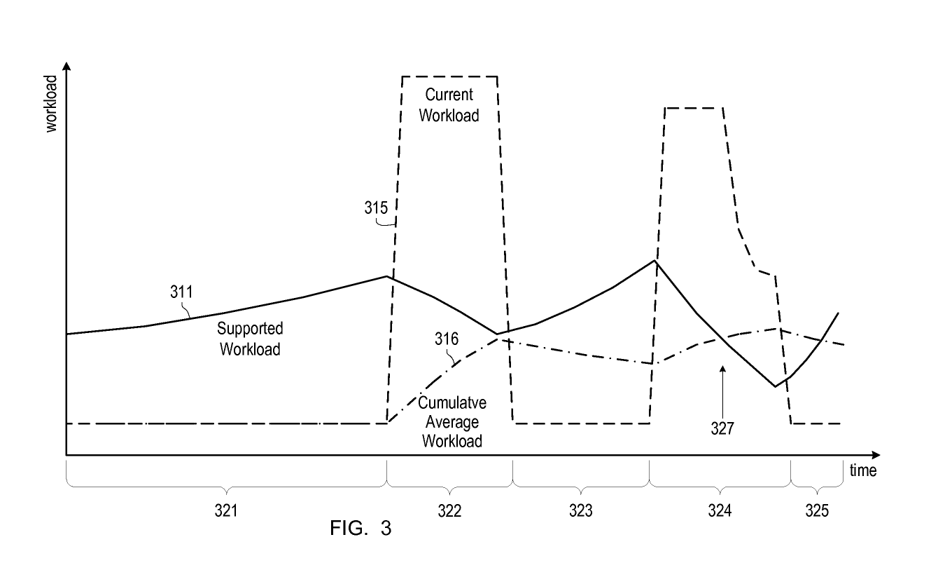

FIG. 3 is a graph that illustrates an example of smart power scheduling using the electronic device of FIG. 1 and the process of FIG. 2. The graph shows a supported average workload 311, a current workload 315, and a cumulative average workload 316. The x-axis of the graph is time. The example of FIG. 3 spans 10 hours. The y-axis of the graph is current (or another related measure that reflects a rate of battery discharge).

The example includes a first idle phase 321 where the electronic device is not actively used. At the start of the first idle phase 321, the core activity levels are low (or zero) so that the current workload 315 will also be low. Since the current workload 315 is constant throughout the first idle phase 321, the cumulative average workload 316 is also constant. The supported average workload 311 is initially much larger than the current workload 315. Accordingly, the supported average workload 311 increases during the first idle phase 321.

Qualitatively, while the current workload is less than the supported average workload, the device supports an increasingly larger average workload over the decreasing remaining time. For a specific example, consider a starting battery charge of 400 mA-hr, a user-defined battery duration of 10 hours, a current workload (and cumulative average workload) of 10 mA, and the first idle phase 321 lasts 4 hours. At the start of the first idle phase 321, the supported average workload is 40 mA (battery charge of 400 mA-hr divided by remaining time of 10 hours). At the end of the first idle phase 321, the supported average workload is 60 mA (battery charge of 400 mA-hr−10 mA×4 hrs=360 mA-hr divided by remaining time of 6 hours).

A gaming phase 322 follows the first idle phase 321. In the gaming phase 322, the current workload 315 is greatly increased over the first idle phase 321. Accordingly, the cumulative average workload 316 increases and the supported average workload 311 decreases throughout the gaming phase 322. In the example of FIG. 3, the cumulative average workload 316 does not exceed the supported average workload 311. Thus, the smart power scheduler module takes no action to assure the device achieves the user-defined battery duration.

Continuing the above specific example, consider a current workload of 120 mA and a 1.5 hour duration of the gaming phase 322. At the end of the gaming phase 322, the cumulative average workload is 40 mA (time average of 10 mA for 4 hours and 120 mA for 1.5 hours) and the supported average workload is 40 mA (battery charge of 360 mA-hr−120 mA×1.5 hrs=180 mA-hr divided by remaining time of 4.5 hours).

A second idle phase 323 follows the gaming phase 322. In the second idle phase 323, the current workload 315 is greatly decreased over the gaming phase 322. Accordingly, the cumulative average workload 316 decreases and the supported average workload 311 increases throughout the second idle phase 323.

Continuing the above specific example, consider a current workload of 10 mA and a 2 hour duration of the second idle phase 323. At the end of the second idle phase 323, the cumulative average workload is 32 mA (time average of 10 mA for 4 hours, 120 mA for 1.5 hours, and 10 mA for 2 hours) and the supported average workload is 64 mA (battery charge of 180 mA-hr−10 mA×2 hrs=160 mA-hr divided by remaining time of 2.5 hours).

A streaming video phase 324 follows the second idle phase 323. In the streaming video phase 324, the current workload 315 is greatly increased over the second idle phase 323. Accordingly, the cumulative average workload 316 increases and the supported average workload 311 decreases throughout the streaming video phase 324.

At time 327, the cumulative average workload 316 exceeds the supported average workload 311. Accordingly, the smart power scheduler will determine a new power state to lower the current workload. The new power state, in the example of FIG. 3, is not sufficiently low for the device to achieve the user-defined battery duration. Accordingly, the smart power scheduler will determine another new power state to further lower the current workload. If the cumulative average workload 316 remains greater that the supported average workload 311, the smart power scheduler may repeatedly lower the power state. In the example of FIG. 3, the cumulative average workload 316 remains greater that the supported average workload 311 after the smart power scheduler has lowered the power state to the lowest level that provides the streaming video function. Since further reduction is not possible, the device continues to operate but warns the user that the device will not achieve the user-defined battery duration if the current operation continues. The user can then change usage (e.g., terminating streaming video) or forgo operating the electronic device for the user-defined battery duration.

A third idle phase 325 follows streaming video phase 324. In the third idle phase 325, the current workload 315 is again greatly decreased. Accordingly, the cumulative average workload 316 decreases and the supported average workload 311 increases throughout the third idle phase 325. As the device's operating time approaches the user-defined battery duration, the supported average workload 311 increases hyperbolically.

Although embodiments of the invention are described above for particular embodiments, many variations of the invention are possible. For example, the numbers of various components may be increased or decreased. Additionally, features of the various embodiments may be combined in combinations that differ from those described above.

Those of skill will appreciate that the various illustrative blocks and modules described in connection with the embodiments disclosed herein can be implemented in various forms. Some blocks and modules have been described above generally in terms of their functionality. How such functionality is implemented depends upon the design constraints imposed on an overall system. Skilled persons can implement the described functionality in varying ways for each particular application, but such implementation decisions should not be interpreted as causing a departure from the scope of the invention. In addition, the grouping of functions within a module, block, or step is for ease of description. Specific functions or steps can be moved from one module or block or distributed across to modules or blocks without departing from the invention.

The various illustrative logical blocks and modules described in connection with the embodiments disclosed herein can be implemented or performed with a general purpose processor, a digital signal processor (DSP), application specific integrated circuit (ASIC), a field programmable gate array (FPGA) or other programmable logic device, discrete gate or transistor logic, discrete hardware components, or any combination thereof designed to perform the functions described herein. A general-purpose processor can be a microprocessor, but in the alternative, the processor can be any processor, controller, microcontroller, or state machine. A processor can also be implemented as a combination of computing devices, for example, a combination of a DSP and a microprocessor, a plurality of microprocessors, one or more microprocessors in conjunction with a DSP core, or any other such configuration.

The steps of a method or algorithm described in connection with the embodiments disclosed herein can be embodied directly in hardware, in a software module executed by a processor, or in a combination of the two. A software module can reside in RAM memory, flash memory, ROM memory, EPROM memory, EEPROM memory, registers, hard disk, a removable disk, a CD-ROM, or any other form of storage medium. An exemplary storage medium can be coupled to the processor such that the processor can read information from, and write information to, the storage medium. In the alternative, the storage medium can be integral to the processor. The processor and the storage medium can reside in an ASIC.

The above description of the disclosed embodiments is provided to enable any person skilled in the art to make or use the invention. Various modifications to these embodiments will be readily apparent to those skilled in the art, and the generic principles described herein can be applied to other embodiments without departing from the spirit or scope of the invention. Thus, it is to be understood that the description and drawings presented herein represent a presently preferred embodiment of the invention and are therefore representative of the subject matter which is broadly contemplated by the present invention. It is further understood that the scope of the present invention fully encompasses other embodiments that may become obvious to those skilled in the art and that the scope of the present invention is accordingly limited by nothing other than the appended claims.

What is claimed is:

1. A method for power scheduling in an electronic device including a plurality of cores operable in a plurality of power states, the method comprising:
receiving a user-defined battery duration;
receiving activity information from the plurality of cores;
determining, based on the activity information, whether the user-defined battery duration is supported; and
in the case that the user-defined battery duration is not supported, determining a new power state for at least one of the plurality of cores.

2. The method of claim 1, further comprising:
calculating a supported average workload based on a battery charge level; and
calculating a cumulative average workload based on the activity information,
wherein the case that the user-defined battery duration is not supported occurs when the supported average workload is less than the cumulative average workload.

3. The method of claim 2, wherein the supported average workload is calculated as a current battery charge divided by a time remaining in the user-defined battery duration minus a factor to adjust for battery non-linearities.

4. The method of claim 2, wherein calculating the cumulative average workload includes mapping the activity information from the plurality of cores to workload levels and combining the workload levels to produce a current workload.

5. The method of claim 4, further comprising:
calculating the battery charge at a current analysis time by subtracting the current workload multiplied by the duration of an analysis time interval from a previous battery charge; and
analyzing a measured battery charge and the calculated battery charge to refine the mapping of the activity information from the plurality of cores to the workload levels.

6. The method of claim 1, wherein determining the new power state is based at least in part on user preferences.

7. The method of claim 1, further comprising:
determining that the user-defined battery duration is not supported with the new power state; and
providing a warning that the user-defined battery duration is not supported.

8. An electronic device, comprising:
a plurality of cores configured to provide functions of the electronic device and operable in a plurality of power states;
a power manager module; and
a smart power scheduler module configured to
receive a user-defined battery duration,
receive activity information from the plurality of cores,
determine, based on the activity information, whether a user-defined battery duration is supported,
in the case that the user-defined battery duration is not supported, determine a new power state for at least one of the plurality of cores, and
signal the new power state to the power manager module,
wherein the power manager module is configured to control the power states of the plurality of cores based at least in part on the new power state signaled by the smart power scheduler module.

9. The electronic device of claim 8, wherein the power manager module is further configured to control the power states of the plurality of cores based at least in part on a use case of the electronic device.

10. The electronic device of claim 8, wherein the smart power scheduler module is further configured to:
calculate a supported average workload based on battery charge level; and
calculate a cumulative average workload based on the activity information,
wherein the case that the user-defined battery duration is not supported occurs when the supported average workload is less than the cumulative average workload.

11. The electronic device of claim 10, wherein the smart power scheduler module calculates the supported average workload as a current battery charge divided by a time remaining in the user-defined battery duration minus a factor to adjust for battery non-linearities.

12. The electronic device of claim 10, wherein calculating the cumulative average workload includes mapping the activity information from the plurality of cores to workload levels and combining the workload levels to produce a current workload.

13. The electronic device of claim 12, the smart power scheduler module is further configured to:
calculate the battery charge at a current analysis time by subtracting the current workload multiplied by the duration of an analysis time interval from a previous battery charge; and
analyze a measured battery charge and the calculated battery charge for use in mapping of the activity information from the plurality of cores to the workload levels.

14. The electronic device of claim 8, wherein the smart power scheduler module is configured to determine the new power state based at least in part on user preferences.

15. The electronic device of claim 8, wherein the smart power scheduler module is further configured to:
determine that the user-defined battery duration is not supported with the new power state; and
generate a warning that the user-defined battery duration is not supported.

16. An apparatus, comprising:
a plurality of cores configured to provide functions of the apparatus and operable in a plurality of power states; and
a means for controlling the power states of the plurality of cores configured to
receive a defined battery duration from a user,
receive activity information from the plurality of cores,
determine, based on the activity information, whether a user-defined battery duration is supported, and
in the case that the user-defined battery duration is not supported, determine a new power state for at least one of the plurality of cores.

17. The apparatus of claim 16, wherein the means for controlling the power states is further configured to:
calculate a supported average workload based on battery charge level; and
calculate a cumulative average workload based on the activity information,
wherein the case that the user-defined battery duration is not supported occurs when the supported average workload is less than the cumulative average workload.

18. The apparatus of claim 17, wherein means for controlling the power states is configured to calculate the supported average workload as a current battery charge divided by a time remaining in the user-defined battery duration minus a factor to adjust for battery non-linearities.

19. The apparatus of claim 17, wherein calculating the cumulative average workload includes mapping the activity information from the plurality of cores to workload levels and combining the workload levels to produce a current workload.

20. The apparatus of claim 16, wherein the means for controlling the power states is configured to determine the new power state based at least in part on user preferences.
